(19) United States
(12) Patent Application Publication
(10) Pub. No.: US 2009/0124082 A1
(43) Pub. Date: May 14, 2009

(54) SLURRY FOR POLISHING RUTHENIUM AND METHOD FOR POLISHING USING THE SAME

(75) Inventors: Hyung-Soon PARK, Icheon-si (KR); Jin-Woong Kim, Icheon-si (KR); Noh-Jung Kwak, Icheon-si (KR); Yong-Soo Choi, Icheon-si (KR); Jong-Han Shin, Icheon-si (KR); Cheol-Hwi Ruy, Icheon-si (KR); Jum-Yong Park, Icheon-si (KR); Sung-Jun Kim, Icheon-si (KR); Jin-Goo Park, Ansan (KR); In-Kwon Kim, Ansan (KR); Tae-Young Kwon, Ansan (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Ichon-shi (KR)

(21) Appl. No.: 12/165,252

(22) Filed: Jun. 30, 2008

(30) Foreign Application Priority Data
Nov. 8, 2007 (KR) 2007-0113859

(51) Int. Cl. H01L 21/304; C09K 3/14

(52) U.S. Cl. 438/693; 51/307; 51/309; 257/E21.237

(57) ABSTRACT

A slurry for polishing a ruthenium layer comprises distilled water, sodium periodate (NaIO₄), an abrasive and a pH controlling agent.

### CROSS-REFERENCE TO RELATED APPLICATIONS

The present invention claims priority of Korean patent application number 10-2007-0113859 filed on Nov. 8, 2007, which is incorporated by reference in its entirety.

### BACKGROUND OF THE INVENTION

The present invention relates to a fabricating method for a semiconductor device, and more particularly, to a slurry for polishing a layer containing ruthenium (Ru) which can decrease the generation of poisonous gas and improve the etch selectivity with an oxide layer.

A capacitor in a semiconductor device includes metal as a lower electrode according to a conventional method. The capacitor including metal refers to as a metal-insulator-metal (MIM) structure capacitor. Platinum group metals are suggested for a metal lower electrode such as platinum (Pt), ruthenium (Ru) and iridium (Ir) in the MIM structure capacitor. Ruthenium is easy to process compared to other materials in the platinum group metals since the ruthenium has good mechanical and chemical characteristics. Thus, ruthenium may be used for forming a lower electrode.

After the lower electrode including ruthenium is formed, a high dielectric layer and an upper electrode are formed over the lower electrode, the individual capacitors are formed by separating and planarizing each of the capacitors through a chemical mechanical polishing (CMP) process. This CMP process requires a slurry for the etching. However, ruthenium is hard to etch by a wet etching at normal temperatures.

Recently, a mixture of nitric acid (HNO₃) and ceric-ammonium nitrate {(NH₄)₂Ce(NO)₆} or potassium hydroxide (KOH) and potassium permanganate (KMnO₄) has been provided which can etch ruthenium. However, these mixtures are a strong acid and a strong base, respectively.

The mixture of the nitric acid and the ceric-ammonium nitrate produce a strong acid and can be harmful to the health of workers. Furthermore, when the mixture of the nitric acid and the ceric-ammonium nitrate is used as the slurry, a poisonous gas may be generated and contamination may occur from by by-products after the CMP process.

When the mixture of the potassium hydroxide and the potassium permanganate is used as a slurry, an oxide layer, which is an insulation material, is etched fast. Thus, an etch selectivity of a ruthenium to an oxide layer may be too low and erosion of a ruthenium layer may occur.

### SUMMARY OF THE INVENTION

Embodiments of the present invention relate to a slurry for polishing a ruthenium layer. The slurry is capable of preventing the generation of poisonous gases, the generation of contamination caused by by-products, the erosion of ruthenium, and capable of ensuring an etch selectivity of a ruthenium layer.

Furthermore, embodiments of the present invention relate to a slurry for polishing a ruthenium layer to have a high etch selectivity of the ruthenium to other materials, ensuring a high removal rate of the ruthenium layer.

In accordance with an aspect of the present invention, there is provided slurry for polishing a ruthenium (Ru) layer. The slurry includes distilled water, sodium periodate (NaIO₄), an abrasive and a pH controlling agent.

In accordance with another aspect of the present invention, there is provided a method for polishing of a ruthenium (Ru) layer. The method includes forming the ruthenium layer over an insulation layer having a recessed portion on a surface of the insulation layer, and polishing the ruthenium layer over outward of the recessed portion of the insulation layer by using slurry of distilled water, sodium periodate, an abrasive and a pH controlling agent.

### BRIEF DESCRIPTION OF THE DRAWINGS

FIG. 1 illustrates a graph of a removal rate of a ruthenium (Ru) layer according to changes of concentration of sodium periodate (NaIO₄) in a slurry.

FIG. 2 illustrates a graph of a removal rate of a ruthenium layer according to changes of concentration of aluminum oxide (Al₂O₃) in a slurry.

FIG. 3 illustrates a graph of a removal rate of a ruthenium layer according to changes in pressure during a polishing process.

FIG. 4 illustrates a graph of a removal rate of a ruthenium layer and a tetra ethyl ortho-silicate (TEOS) layer and a etch selectivity of the ruthenium layer to the TEOS layer according to pH level of a slurry.

FIG. 5 illustrates a graph of a removal rate of a ruthenium layer according to changes of molarity (M) of the NaIO₄, orthoperiodic acid (H₅IO₆), and potassium periodate (KIO₄) in the slurries.

FIG. 6 illustrates a graph of degree of formation of a ruthenium oxide layer over a ruthenium layer according to changes of molarities of NaIO₄, H₅IO₆ and KIO₄ in the slurries.

FIGS. 7A to 7D illustrate cross-sectional views of a method for fabricating a capacitor using a slurry according to one embodiment of the present invention.

### DESCRIPTION OF SPECIFIC EMBODIMENTS

According to the present invention, as a ruthenium (Ru) layer is planarized by using sodium periodate (NaIO₄) as a slurry, a high removal rate of a ruthenium layer can be achieved. Also an etch selectivity of the ruthenium layer to a ruthenium oxide layer can be ensured and planarizing characteristics can be improved. Thus, device separation processes can be improved.

In a chemical mechanical polishing (CMP) process a slurry chemically includes an oxidizing agent which oxidizes ruthenium by removing an electron from the ruthenium, and then the oxidized ruthenium layer may be removed by a polishing process. Furthermore, slurry mechanically includes abrasive such as silicon dioxide (SiO₂) or cerium oxide (CeO₂). The abrasive is used for polishing an oxidized ruthenium layer. A polishing pad is compressed on a ruthenium layer and then the polishing pad moves over the ruthenium layer in order to remove the oxidized ruthenium layer while supplying the slurry.

After removing the oxidized ruthenium layer, non-oxidized ruthenium layer is exposed therefore newly exposed ruthenium layer is also oxidized, thereby forming a second oxidized layer. The second oxidized layer is also removed using the polishing pad. This process is repeated until the ruthenium layer has a given thickness.

In accordance with an embodiment of the present invention, slurry for a CMP process of a ruthenium layer is fabricated by using sodium periodate (NaIO₄) as an oxidizing agent.

Slurry for the CMP of the ruthenium layer according to the present invention includes deionized (DI) water, sodium periodate (NaIO₄) and abrasives. Furthermore, the slurry includes a pH controlling agent. The pH level can range from approximately 4 to approximately 10. The sodium periodate has a molarity ranging from approximately 0.01 M to approximately 10 M, the abrasive has a concentration ranging from approximately 0.1 wt % to approximately 20 wt % in the slurry. It is preferable that the sodium periodate has molarity ranging from approximately 0.01 M to approximately 1 M, the abrasive has a weight percent ranging from approximately 0.1 wt % to approximately 5 wt %, and the pH level of the slurry ranges approximately 5.5 to approximately 6.5.

Sodium periodate provides periodate ions (IO₄⁻) which may oxidize ruthenium. The periodate ions (IO₄⁻) oxidizes ruthenium as follows.

7Ru(s)+4IO₄⁻+4H⁺→7RuO₂+2I₂+2H₂O

Ruthenium oxide may be formed having an oxidation state of +4 ions like ‘RuO₂’. The ruthenium is oxidized having an oxidation state of +4 ions since a pH level of slurry in accordance with the present invention is maintained at a range from approximately 5.5 to approximately 6.5 (weak acid).

When a slurry is a strong acid (pH level is less than approximately 3), a ruthenium oxide may be formed having an oxidation state of +8 ions like ‘RuO₄’. However, the ‘RuO₄’ is unsuitable for fabricating a semiconductor device and it is known to those skilled in the art since the ‘RuO₄’ is highly explosive and highly poisonous.

A method for fabricating slurry in accordance with the present invention is described as follows. Sodium periodate (NaIO₄) used as an oxidizing agent is stirred into distilled water, wherein an amount of the oxidizing agent added ranges from approximately 0.01 M to approximately 10 M, and a pH controlling agent is added so as to control a pH level. After controlling the pH level, abrasive is added, wherein an amount of the abrasive added ranges from approximately 0.1 wt % to approximately 20 wt %.

The sodium periodate may etch ruthenium effectively and produce a passivation layer. Furthermore, when concentration of the sodium periodates is increased, an etch rate of the ruthenium is increased. Thus, when a slurry is fabricated by using those characteristics, a pH level of the slurry can be easily controlled by adding pH controlling agent.

When the sodium periodate is dissolved in the distill water, a pH level is approximately 4.5. However, the pH level may be controlled so as to control a removal rate and an etch selectivity of a ruthenium layer. When slurry is a strong acid, the slurry is harmful to human health and can generate poisonous gases. When slurry is a strong base, the slurry is also harmful to human health and an etch selectivity of a ruthenium layer may be caused since the slurry etches a ruthenium oxide layer faster than the ruthenium layer. Thus, the pH level of a slurry may be controlled to have a range from approximately 4 to approximately 10, which is in a range of weak acid, neutrality and weak base.

Therefore, the pH controlling agent used to improve the removal rate and the selectivity of the ruthenium layer includes an acidity controlling agent or an alkalinity controlling agent. The acidity controlling agent is used to control a pH level to be a weak acid. The acidity controlling agent includes hydrogen chloride (HCl), nitric acid (HNO₃), sulfuric acid (H₂SO₄) or phosphoric acid (H₃PO₄). Furthermore, the alkalinity controlling agent is used to control a pH level of slurry to be a weak base. The alkalinity controlling agent includes ammonium hydroxide (NH₄OH), potassium hydroxide (KOH), sodium hydroxide (NaOH), tetramethylammonium hydroxide (TMAH) or tetramethyl ammonium (TMA).

The abrasive includes one selected from the group consisting of aluminum oxide (Al₂O₃), silicon dioxide (SiO₂), cerium oxide (CeO₂), zirconium oxide (ZrO₂) and a combination thereof. Preferably, aluminum oxide may be used as the abrasive to polish a ruthenium layer effectively since the intensity of aluminum oxide is relatively stronger than that of other abrasives.

Experimental examples of the present invention are described as follows. The examples are performed using a Rohm and Haas IC1400 pad with CMP equipment (POLI-500; G&P Tech.). The experimental examples are performed while rotational speeds of a platen and a head are fixed at approximately 50 revolutions per minute (RPM). Furthermore, a ratio of supplying slurry is approximately 140 ml/min and polishing is performed for 1 minute. The examples except a third experimental example and a fourth experimental example are performed at a pressure approximately 5 psi (lb/inch²).

In the first experimental example, removal rates of ruthenium layer according to changes of concentration of sodium periodate (NaIO₄) are measured. Sodium periodate of 0.01 M, 0.02 M, 0.06 M and 0.1 M are respectively added in distilled water and then ammonium hydroxide is added into solutions in order to control pH levels of the solutions to approximately 9. Then, aluminum oxide (used as an abrasive) of approximately 1 wt % is added, thereby fabricating a slurry.

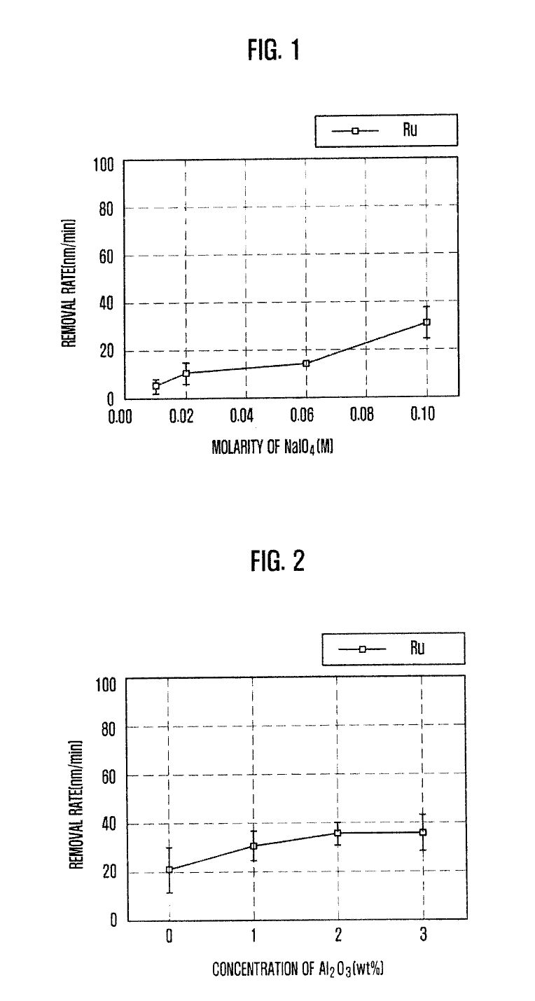

FIG. 1 illustrates a graph of a removal rate of a ruthenium layer according to the changes of concentration of the sodium periodate (NaIO₄). It is shown that, as concentration of sodium periodate is increased, an etch rate of ruthenium layer is increased. For further details, since the etch rate of the ruthenium layer is increased, a thickness of a passivation layer is increased. Thus, the removal rate of a ruthenium layer will be increased because of an increase in the etch rate of the ruthenium layer and formation and removal of the passivation layer.

In the second experimental example, removal rate of ruthenium layer according to changes of concentration of aluminum oxide (Al₂O₃) added as an abrasive is measured. After adding 0.1 M sodium periodate (NaIO₄) in distilled water, ammonium hydroxide is added in solution in order to control the pH level of the solutions to approximately 9, and then 0 wt % aluminum oxide, 1 wt % aluminum oxide, 2 wt % aluminum oxide and 3 wt % aluminum oxide are added in the solutions, respectively, thereby fabricating the slurries.

FIG. 2 illustrates a graph of a removal rate of a ruthenium layer according to changes of concentrates of aluminum oxide. The removal rate of the ruthenium layer is increased up to 35 nm/min as the concentration of aluminum oxide is increased, however, the removal rate of the ruthenium layer does not increase any more when the concentration of aluminum oxide is over 2 wt %. For further details, since formation rate of a passivation layer becomes uniform past a certain concentration of the aluminum oxide, although mechanical removal is enhanced by increasing of the aluminum oxide, it cannot help increase removal rate of the ruthenium layer over a certain removal rate of the ruthenium layer.

In the third experimental example, removal rates of a ruthenium layer according to changes of pressure during a removal process are measured. After adding 0.1 M sodium periodate (NaIO₄) in distilled water, ammonium hydroxide is added in solution in order to control a pH level of the solutions to approximately 9, and then 2 wt % aluminum oxide is added in the solutions, thereby fabricating the slurries. The removal process of the ruthenium layer is performed while the pressure is changed to 1 psi, 2 psi, 3 psi and 4 psi, respectively.

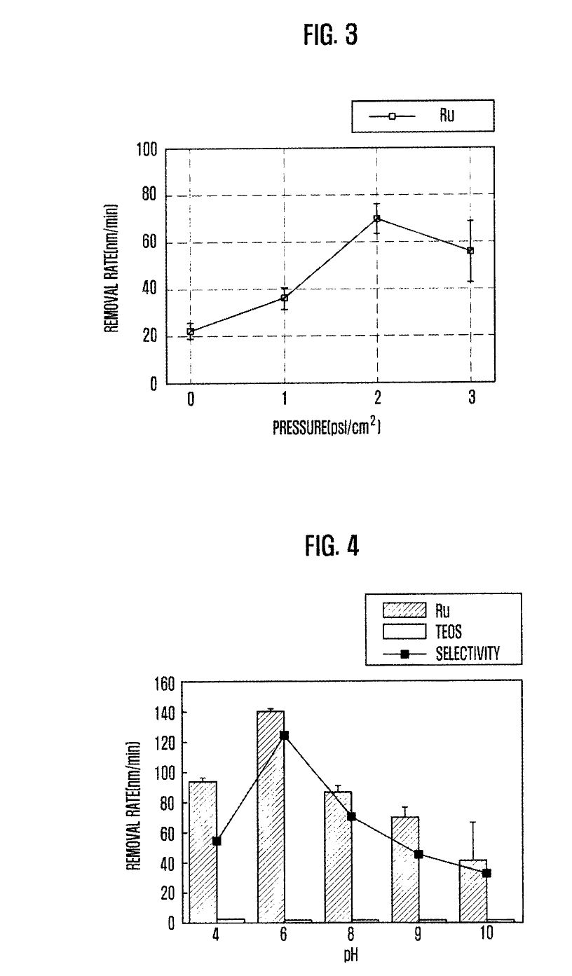

FIG. 3 illustrates a graph of removal rates of a ruthenium layer according to changes of pressure. The removal rate of the ruthenium layer is approximately 70 nm/min at a pressure of approximately 4 psi, however, although the pressure is increased over 4 psi, the removal rate of the ruthenium layer does not increase any more. For further details, as in the second experimental example, although mechanical removal is enhanced by increasing the pressure in the removal process, it does not help increasing removal rate of the ruthenium layer over a certain removal rate.

In the fourth experimental example, removal rates of a ruthenium layer and a tetra ethyl ortho-silicate (TEOS) layer according to changes of a pH level of a slurry are measured. After adding 0.1 M sodium periodate in distilled water, pH levels of solutions are controlled to be 4, 6, 8, 9 and 10, respectively, by adding ammonium hydroixde, and then 2 wt % aluminum oxide is added into the solutions, thereby fabricating a slurry.

FIG. 4 illustrates a graph of removal rates of a ruthenium layer and a TEOS layer and an etch selectivity of the ruthenium layer to the TEOS layer according to changes of the pH level of a slurry. When the pH level of the slurry is 6, the highest removal rate of the ruthenium layer is approximately 140 nm/min. Furthermore, when the pH level of the slurry is 6, a ratio of etch rates between the ruthenium layer to the TEOS layer is approximately 90:1, which is the biggest etch rate difference between the ruthenium layer and the TEOS layer. Thus, when the pH level of slurry is 6, excellent removal characteristics are shown.

In the comparative example, orthoperiodic acid (H₅IO₆) and potassium periodate (KIO₄) are respectively applied as an oxidizing agent for fabricating slurry instead of sodium periodate (NaIO₄), wherein H₅IO₆ and KIO₄ are periodic acids such as sodium periodate (NaIO₄). When H₅IO₆, KIO₄ and NaIO₄ are respectively used for fabricating slurries, characteristics of the slurries are compared as follows.

Table 1 below compares properties of slurries according to changes of molarities of periodic acids.

TABLE 1

| Periodic acids | Molarities (M) | pH levels (pH) |
|---|---|---|
| H₅IO₆ | 0.01 | 1.95 |
| | 0.02 | 1.60 |
| | 0.06 | 1.20 |
| | 0.10 | 1.02 |
| KIO₄ | 0.01 | 4.74 |
| | 0.02 | 4.79 |
| | 0.06 | 4.86 |
| | 0.10 | 4.80 |
| NaIO₄ | 0.01 | 5.97 |
| | 0.02 | 5.20 |
| | 0.06 | 4.64 |
| | 0.10 | 4.42 |

When H₅IO₆ is applied for fabricating a slurry, poisonous RuO₄ gas is generated since H₅IO₆ is a strong acid. Furthermore, H₅IO₆ is harmful to human health since H₅IO₆ is a strong acid and it is hard to control pH levels when H₅IO₆ is applied.

In the meantime, when KIO₄ is applied for fabricating a slurry, pH levels of slurries have a range similar to a range of pH levels of slurries fabricated by using NaIO₄.

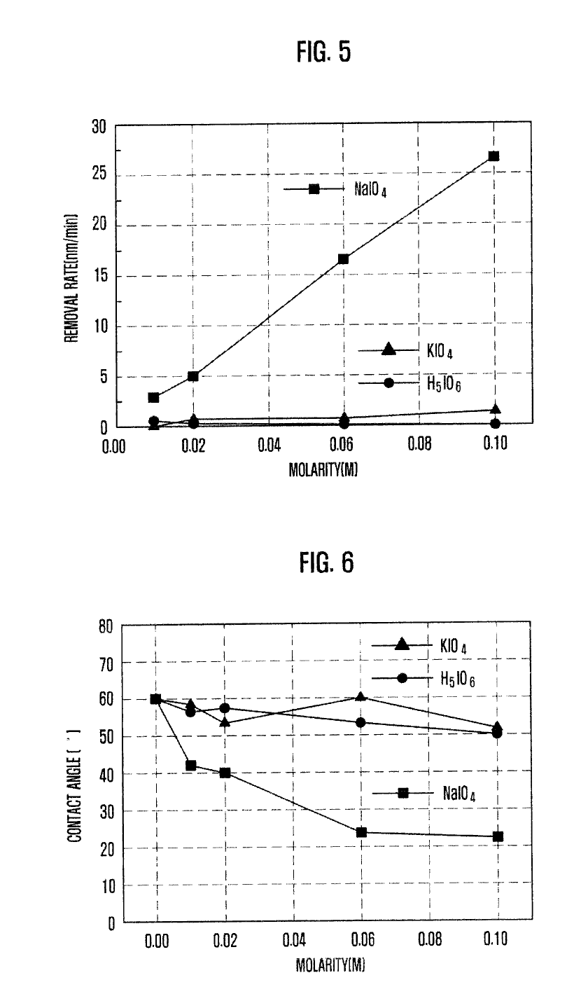

FIG. 5 illustrates a graph of removal rates of ruthenium layer according to changes of molarity (M) of the NaIO₄, H₅IO₆, and KIO₄ in slurries. The removal rates of the ruthenium layer are increased as molarity of NaIO₄ is increased, however, when H₅IO₆ and KIO₄ are applied as an oxidizing agent, although molarities of H₅IO₆ and KIO₄ are increased, it does not affect the removal rate of the ruthenium layer.

Although molarities of H₅IO₆ and KIO₄ in the slurries are the same as molarity of NaIO₄ in a slurry, the removal rate of the ruthenium layer when H₅IO₆ and KIO₄ are applied as an oxidizing agent in the slurries is less than the removal rate of the ruthenium layer when NaIO₄ is applied as an oxidizing agent in a slurry. Furthermore, the removal rate of the ruthenium layer when H₅IO₆ and KIO₄ are applied as an oxidizing agent is less than the removal rate of the ruthenium layer when NaIO₄ is applied as an oxidizing agent in every molarity of the slurries.

Furthermore, since KIO₄ has remarkably low solubility in distilled water, although a solution of KIO₄ in distilled water is stirred for over 2 hours when molarity of KIO₄ in slurry is over 0.06 M, KIO₄ does not dissolve in the distilled water. However, although KIO₄ may melt in slurry when the molarity of KIO₄ in the slurry is under 0.03 M, the slurry may not etch the ruthenium layer. Thus, KIO₄ is not a suitable slurry for polishing ruthenium.

FIG. 6 illustrates a graph of degree of formation of a ruthenium oxide layer over a ruthenium layer according to changes of molarities of NaIO₄, H₅IO₆ and KIO₄ in slurries. The degree of formation of the ruthenium oxide layer is measured by a contact angle.

In FIG. 6, when slurries fabricated by using NaIO₄, H₅IO₆ and KIO₄ are used for polishing the ruthenium layer, contact angles of a ruthenium layer polished by slurries using H₅IO₆ and KIO₄ are higher than that of a ruthenium layer polished by a slurry fabricated by using NaIO₄ in a range of molarity used in the experiments. Furthermore, there are not big differences in changes of the contact angles of the ruthenium layer polished by slurries using H₅IO₆ and KIO₄. This result shows that the ruthenium oxide layer formed by polishing the ruthenium layer with slurries using H₅IO₆ and KIO₄ is not formed as well as the ruthenium oxide layer formed by polishing the ruthenium layer with a slurry fabricated by using NaIO₄.

Arrangement of the results of above-mentioned Table 1, FIGS. 5 and 6 will be showed as follows.

When H₅IO₆ melts in distilled water in order to fabricate a slurry, positive hydrogen ion (H⁺) is produced. The slurry fabricated by using H₅IO₆ becomes a strong acid since the positive hydrogen ion H⁺ is produced. When the slurry is the strong acid, a ruthenium oxide (RuO₄) gas may be produced when the slurry is used for polishing a ruthenium layer, wherein the RuO₄ is highly poisonous and harmful to human health.

Furthermore, when slurry is fabricated by applying H₅IO₆, it is hard to control a pH level of the slurry. When a ruthenium layer is polished by slurries using H₅IO₆, a removal rate of the ruthenium layer polished by the slurry fabricated by using H₅IO₆ is lower than that of the ruthenium layer polished by the slurry fabricated by using NaIO₄. Moreover, contact angles of the ruthenium layer polished by a slurry using H₅IO₆ is higher than that of the ruthenium layer polished by the slurry fabricated using NaIO₄. The higher contact angle of the polished ruthenium layer represents a lower degree of oxidation.

When slurry is fabricated by using KIO₄, although a pH level of the slurry is similar to that of slurry fabricated by using NaIO₄, it is hard to use KIO₄ for fabricating slurry since solubility of KIO₄ to distilled water is remarkably low. Moreover, when a ruthenium layer is polished by using the slurry fabricated by using KIO₄, a removal rate of the ruthenium layer polished by the slurry fabricated by using KIO₄ is lower than that of the ruthenium layer polished by the slurry fabricated using NaIO₄, and contact angles of the ruthenium layer polished by slurries using KIO₄ is higher than that of the ruthenium layer polished by a slurry fabricated using NaIO₄. The higher contact angle of the polished ruthenium layer represents a lower degree of oxidation.

When slurry is fabricated by using NaIO₄, a pH level of NaIO₄ in the slurry has a range from weak acid to close to neutral and a pH level of NaIO₄ is easy to control compared to other chemicals. Further, when the slurry fabricated using NaIO₄ is used to polish a ruthenium layer, a removal rate of the ruthenium layer is higher than that of the ruthenium layer polished using slurries fabricated using aforementioned chemicals, and it is easy to form a ruthnium oxide layer on a surface of the ruthenium layer during polishing of the ruthenium layer.

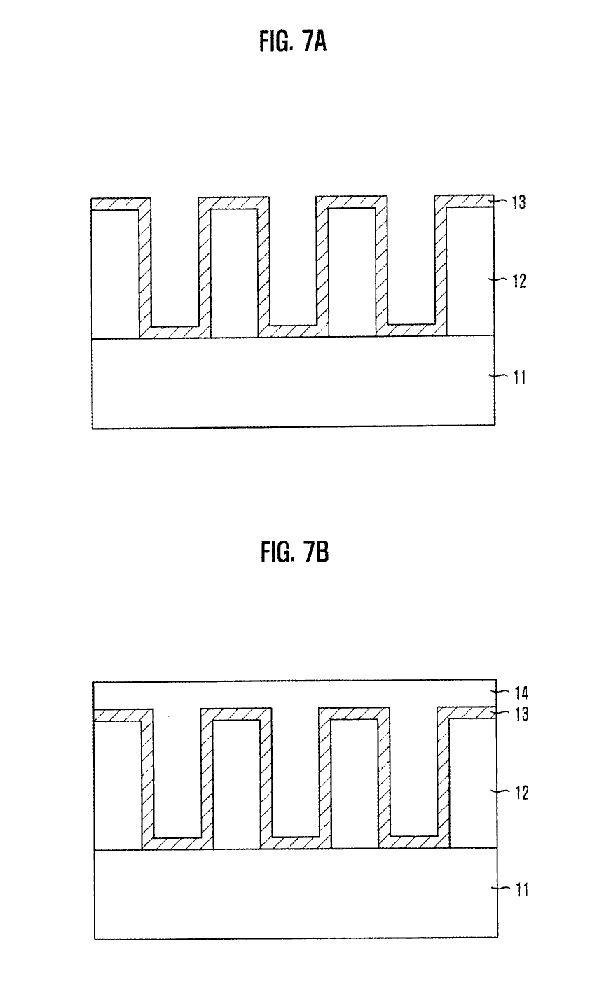

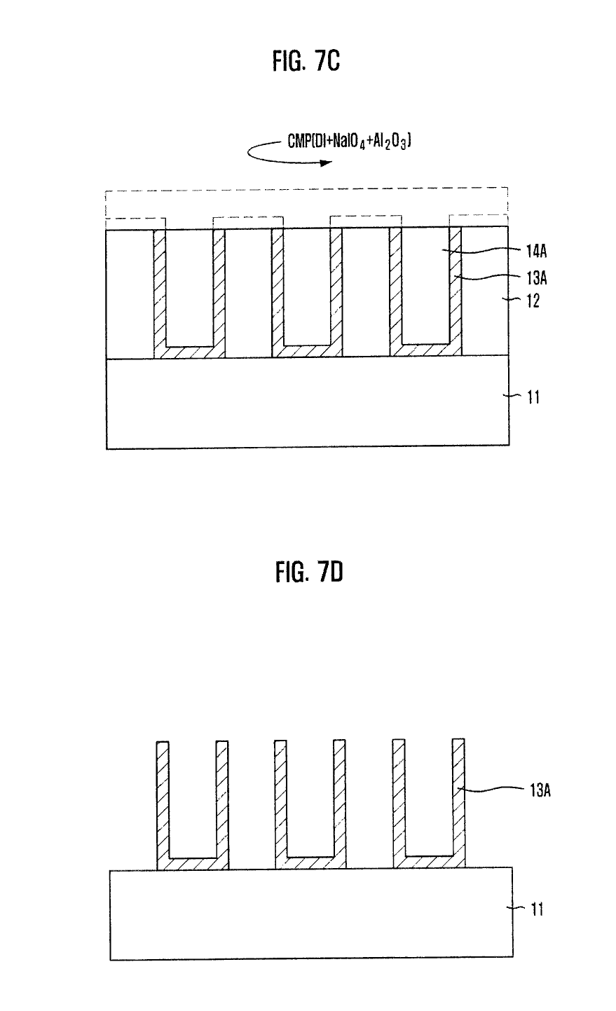

FIGS. 7A to 7D illustrate cross-sectional views of a method for fabricating a capacitor using a slurry according to an embodiment of the present invention. In FIG. 7A, an insulation layer 12 is formed over a lower layer 11. The lower layer 11 may include a substrate having a transistor and bit line, etc., and may include a landing plug contact and a storage node contact. The insulation layer 12 includes an oxide layer and may include a phosphosilicate glass (PSG) layer and a plasma enhanced-tetra ethyl ortho-silicate (PETEOS) layer.

Patterning process is performed on the insulation layer 12 in order to form an open region defining a lower electrode target region, and then a conductive layer 13 is formed over a patterned surface. The conductive layer 13 would be used as the lower electrode. The conductive layer 13 includes a polysilicon layer, a titanium nitride (TiN) layer and a ruthenium layer. In one embodiment, the conductive layer 13 consists essentially of a ruthenium layer. The thickness of the conductive layer 13 ranges from approximately 100 Å to approximately 1,000 Å, desirably ranging from approximately 100 Å to approximately 500 Å.

Referring to FIG. 7B, a capping layer 14 is formed over the conductive layer 13. The capping layer 14 is used to prevent contamination of the lower electrode having a cylindrical structure formed in the open region during a subsequent chemical mechanical polishing (CMP) process. The capping layer 14 may include a photoresist layer or an oxide layer.

Referring to FIG. 7C, the CMP process is performed over the capping layer 14 to separate the lower electrode. In other words, as a portion of the conductive layer 13 is polished by the CMP process, the lower electrode 13A having a cylindrical structure remains in the open region. The CMP process may be performed by using a slurry including distilled water, sodium periodate (NaIO₄), abrasive and pH controlling agent. Reference numeral 14A represents remaining capping layer 14 after the CMP process.

A pH level of the slurry ranges from approximately 4 to approximately 10 by adding the pH controlling agent. The pH controlling agent includes an acidity controlling agent or alkalinity controlling agent. The acidity controlling agent includes hydrochloric acid (HCl), nitric acid (HNO₃), sulphuric acid (H₂SO₄) or phosphoric acid (H₃PO₄), and the alkalinity controlling agent includes ammonium hydroxide (NH₄OH), potassium hydroxide (KOH), sodium hydroxide (NaOH), tetramethylammonium hydroxide (TMAH) or tetramethyl ammonium (TMA).

The abrasive includes one selected from the group consisting of aluminum oxide (Al₂O₃), silicon dioxide (SiO₂), cerium oxide (CeO₂), zirconium oxide (ZrO₂) and a combination thereof. Desirably, the abrasive includes aluminum oxide.

Furthermore, molarity of NaIO₄ in the slurry can range from approximately 0.1 M to approximately 10 M, and concentration of the abrasive in the slurry can range from approximately 0.1 wt % to approximately 20 wt %.

Referring to FIG. 7D, after removing an etched capping layer 14A, the insulation layer 12 is removed through a wet dip out process. When the capping layer 14 is a photoresist layer, the etched capping layer 14A is removed using plasma. When the capping layer 14 is an oxide layer, the etched capping layer 14A and the insulation layer 12 are removed during the wet dip-out process. The wet dip-out process is performed by using hydrogen fluoride (HF) or buffered oxide etchants (BOE) since the insulation layer 12 is an oxide layer.

While the present invention has been described with respect to the specific embodiments, the above embodiments of the present invention are illustrative and not limitative. It will be apparent to those skilled in the art that various changes and modifications may be made without departing from the spirit and scope of the invention as defined in the following claims.

What is claimed is:

1. A slurry for polishing a ruthenium layer comprises distilled water, sodium periodate (NaIO₄), an abrasive and a pH controlling agent.

2. The slurry in claim 1, wherein a pH level of the slurry ranges from approximately 4 to approximately 10 by adding the pH controlling agent.

3. The slurry in claim 2, wherein the pH level of the slurry ranges from approximately 5.5 to approximately 6.5 by adding the pH controlling agent.

4. The slurry in claim 1, wherein the pH controlling agent comprises an acidity controlling agent and an alkalinity controlling agent.

5. The slurry in claim 4, wherein the acidity controlling agent comprises hydrochloric acid (HCl), nitric acid (HNO₃), sulphuric acid (H₂SO₄) or phosphoric acid (H₃PO₄).

6. The slurry in claim 4, wherein the alkalinity controlling agent comprises ammonium hydroxide (NH₄OH), potassium hydroxide (KOH), sodium hydroxide (NaOH), tetramethylammonium hydroxide (TMAH) or tetramethyl ammonium (TMA).

7. The slurry in claim 1, wherein the abrasive comprises aluminum oxide (Al₂O₃).

8. The slurry in claim 1, wherein molarity of the sodium periodate is no more than 10 M.

9. The slurry in claim 1, wherein concentration of the aluminum oxide is no more than 20 wt %.

10. The slurry in claim 1, wherein the abrasive comprises one selected from the group consisting of silicon dioxide (SiO₂), cerium oxide (CeO₂), zirconium oxide (ZrO₂), and a combination thereof.

11. A method for polishing a ruthenium (Ru) layer, the method comprising:
providing an insulation layer having a recess portion over a substrate:
forming the ruthenium layer over the insulation layer having the recessed portion, the ruthenium layer being formed within and outside of the recessed portion; and
polishing a portion of the ruthenium layer provided outside of the recessed portion of the insulation layer by using a slurry including distilled water, sodium periodate, an abrasive and a pH controlling agent.

12. The method in claim 11, wherein a pH level of the slurry ranges from approximately 4 to approximately 10 by adding the pH controlling agent.

13. The method in claim 12, wherein the pH controlling agent comprises an acidity controlling agent and an alkalinity controlling agent.

14. The method in claim 13, wherein the acidity controlling agent comprises hydrochloric acid (HCl), nitric acid (HNO₃), sulphuric acid (H₂SO₄) or phosphoric acid (H₃PO₄).

15. The method in claim 13, wherein the alkalinity controlling agent comprises ammonium hydroxide (NH₄OH), potassium hydroxide (KOH), sodium hydroxide (NaOH), tetramethylammonium hydroxide (TMAH) or tetramethyl ammonium (TMA).

16. The method in claim 11, wherein the abrasive comprises aluminum oxide (Al₂O₃).

17. The method in claim 11, wherein molarity of the sodium periodate is no more than 10 M.

18. The method in claim 11, wherein concentration of the aluminum oxide is no more than 20 wt %.

19. The method in claim 11, wherein wherein the abrasive comprises one selected from the group consisting of silicon dioxide (SiO₂), cerium oxide (CeO₂), zirconium oxide (ZrO₂), and a combination thereof.

20. The method in claim 11, wherein the insulation layer comprises an oxide layer.

21. The method in claim 20, wherein the oxide layer comprises a tetra ethyl ortho-silicate (TEOS) layer.

22. The method in claim 11, wherein the ruthenium layer is polished until the portion of the ruthenium layer provided outside of the recessed portion is substantially removed and the remaining portion of the ruthenium defines an electrode of a capacitor.
